(19) United States
(12) Patent Application Publication
(10) Pub. No.: US 2025/0386452 A1
(43) Pub. Date: Dec. 18, 2025

(54) MOTOR CONTROLLER AND COLD PLATE ASSEMBLY

(71) Applicant: Delta Electronics, Inc., Taoyuan City (TW)

(72) Inventors: Yi-Syuan Li, Taoyuan City (TW); Ching-Chuan Hsu, Taoyuan City (TW); Shih-Ming Yan, Taoyuan City (TW)

(21) Appl. No.: 19/072,232

(22) Filed: Mar. 6, 2025

Related U.S. Application Data
(60) Provisional application No. 63/661,160, filed on Jun. 18, 2024.

(30) Foreign Application Priority Data
Dec. 23, 2024 (CN) 202411898363.1

(51) Int. Cl. H05K 7/20; H02K 5/22; H02K 11/30; H05K 1/02

(52) U.S. Cl. CPC H05K 7/20254; H02K 5/225; H02K 11/30; H05K 1/0203; H05K 7/2039

(57) ABSTRACT

A motor controller and cold plate assembly is disclosed and includes a cold plate, a PCB, a terminal base, a conductive component and a wiring terminal. The cold plate includes a first surface and a second surface opposite to each other, and a through hole. The though hole passes through the first surface and the second surface. The PCB includes a third surface and a fourth surface opposite to each other, and an opening. The fourth surface is attached to the first surface. The opening and the through hole are spatially aligned and communicated to each other. The terminal base is spatially corresponding to the opening and the through hole. The conductive component passes through the through hole, is spaced apart from the cold plate and engaged with the terminal base. The wiring terminal is connected to the conductive component, and extended along the second surface of the cold plate.

### CROSS-REFERENCE TO RELATED APPLICATION

This application claims the benefit of U.S. Provisional Application No. 63/661,160 filed on Jun. 18, 2024, and entitled “MOTOR CONTROLLER AND COLD PLATE ASSEMBLY”. This application claims priority to China Patent Application No. 202411898363.1, filed on Dec. 23, 2024. The entireties of the above-mentioned patent applications are incorporated herein by reference for all purposes.

### FIELD OF THE INVENTION

The present disclosure relates to a motor assembly, and more particularly to a motor controller and cold plate assembly having output copper pillars passing through the cold plate, to achieve the purposes of cooling and saving space at the same time. It allows to combine the glue potting surrounding the output copper pillars with the frame of the cold plate to strengthen the terminal structure.

### BACKGROUND OF THE INVENTION

Recently, cold plates are wildly used in the motor controllers of electric vehicles. Motor driving system plays an important impact on electric vehicle' performance, so thermal design should be considered in the early stages during the motor controller design and layout of the devices.

Generally, the Al-PCB of the motor controller is disposed on the top of the cold plate, and the conventional output terminals are designed with the output terminal structure upwards of the Al-PCB. The output terminal structure disposed on the Al-PCB is simple. Usually, the output terminal structure is composed of at least three copper pillars, and takes up a lot of space above the cold plate. After combining the motor controller and the cold plate, the entire thickness of the system will become thicker. Moreover, since the output terminal structure disposed above the cold plate is led away from the cold plate, the terminal heat dissipation is slow and the cooling effect is poor. In that, the wire sheath may be melted during high power output.

On the other hand, it is not easy to set a reverse terminal output structure of the motor controller combined with the cold plate. The reverse terminal output structure needs to be connected between the Al-PCB on the top surface of the cold plate and the high voltage line parallel to bottom surface of the cold plate. That is, the conductive elements of the terminal output structure are perpendicular to the Al-PCB or the high voltage line. It not conducive to assemble through bolts and nuts parallel to top surface or bottom surface of the cold plate.

Therefore, there is a need of providing a motor controller and cold plate assembly having output copper pillars passing through the cold plate, to achieve the purposes of cooling and saving space at the same time, and obviate the drawbacks encountered from the prior arts.

### SUMMARY OF THE INVENTION

It is an object of the present disclosure to provide a motor controller and cold plate assembly having output copper pillars passing through the cold plate, to achieve the purposes of cooling and saving space at the same time. It allows to combine the glue potting surrounding the output copper pillars with the frame of the cold plate to strengthen the terminal structure. Compared with the conventional output terminal structure protruding from the cold plate or combined through the horizontal screw connection, the output terminal structure of the present disclosure passing through the cold plate is more conducive to reducing the entire thickness of the motor controller and cold plate assembly and enhancing the head dissipation efficiency thereof. Furthermore, the potting component is further formed to enhance the supporting strength between the conductive component and the cold plate and improve the head dissipation efficiency of the output terminal structure. Preferably, the potting component includes a first ring end and a second ring end disposed on two opposite ends to clamp the PCB and the cold plate. It not only reduces the entire thickness of the assembly structure, but also enhance the structural strength of the output terminal structure or provide the waterproof function. In case of that a plurality of output terminal structures are arranged closely, the potting component can be formed into one piece and has first ring ends, ring grooves and connection portions to enhance the structural strength for the output terminal structures. On the other hand, each wiring terminal is connected to the terminal component through the screw, which is screwed along the vertical direction relative the surface of the cold plate. The connection operations of the two adjacent terminal components and the wiring terminals are not interfered with each other. That is, the connection operations of the terminal components and the wiring terminals are simplified. In addition, since the lead-out directions of the wiring terminals are adjustable according to the wiring bases fixed on the cold plate, it provides multiple combination changes and simplifies the assembly process. The present disclosure includes the industrial applicability and the inventive steps.

In accordance with one aspect of the present disclosure, a motor controller and cold plate assembly is provided and includes a cold plate, a PCB, at least one terminal base, at least one conductive component and at least one wiring terminal. The cold plate includes a first surface, a second surface and at least one through hole. The first surface and the second surface are opposite to each other. The at least one though hole passes through the first surface and the second surface. The PCB includes a third surface and a fourth surface opposite to each other, and at least one opening. The fourth surface of the PCB is attached to the first surface of the cold plate for heat dissipation. The at least one opening passes through the third surface and the fourth surface. The at least one opening and the at least one through hole of the cold plate are spatially aligned to each other and in communication with each other. The at least one terminal base is spatially corresponding to the at least one opening of the PCB and the at least one through hole of the cold plate. The at least one terminal base is mounted on the third surface of the PCB. The at least one conductive component passes through the at least one through hole and is spaced apart from the cold plate. The at least one conductive component is engaged with the at least one terminal base. The at least one wiring terminal is connected to the at least one conductive component, and extended along the second surface of the cold plate.

In an embodiment, the at least one terminal base is a SMD punched terminal disposed on the third surface of the PCB and covers the at least one opening of the PCB.

In an embodiment, the terminal base is in shape of a cylinder hat, and includes a seal portion and a ring space, which are in communication with the at least one opening of the PCB after the at least one terminal base is mounted on the third surface of the PCB by a surface mounting technology.

In an embodiment, the at least one conductive component is a copper pillar or a hexagonal stud and includes a first engaged end and a second engaged end disposed on two opposite ends.

In an embodiment, the seal portion and the first engaged end are a recess part and a protrusion part firmly fit with each other.

In an embodiment, the first engaged end passes through the at least one through hole of the cold plate and is inserted into the seal portion of the at least one terminal base for electrical connection.

In an embodiment, the second engaged end of the at least one conductive component includes inner threads and has an opening facing a direction perpendicular to the second surface of the cold plate.

In an embodiment, the at least one conductive component is engaged with the seal portion of the terminal base through the first engaged end, and the second engaged end of the conductive component is exposed and protruded from the second surface of the cold plate.

In an embodiment, the at least one wiring terminal is extended parallel to the second surface and fixed into the second engaged end of the at least one conductive component through a screw.

In an embodiment, the PCB further includes at least one electronic component configured to form a power supply unit. The at least one electronic component is disposed on the third surface of the PCB.

In an embodiment, the motor controller and cold plate assembly further includes a potting component, and the potting component is configured to encapsulate a space formed between the at least one terminal component and the at least one through hole of the cold plate.

In an embodiment, the potting component includes a first ring end and a second ring end disposed on two opposite ends.

In an embodiment, the first ring end is spatially corresponding to a ring space of the at least one conductive base, and received in the ring space. The ring space of the at least one conductive base has a diameter greater than that of the at least one opening of the PCB and that of the at least one through hole of the cold plate, and the diameter of the at least one opening and the diameter of the at least one through hole are equal to each other.

In an embodiment, the cold plate includes an inlet and an outlet. The inlet and the outlet are disposed on a lateral wall of the cold plate and in fluid communication with an inner space of the cold plate, so as to transport a coolant through the inlet and the outlet for heat exchanging.

In an embodiment, the cold plate further includes an expanded opening disposed on the second surface and spatially corresponding to the at least one through hole.

In an embodiment, the at least one through hole is aligned with the expanded opening and in fluid communication with an exterior through the expanded opening.

In an embodiment, the expanded opening has a diameter greater than that of the at least one through hole.

In an embodiment, the diameter of the ring space of the at least one terminal base and the diameter of the expended opening are greater than that of the opening and that of the at least one through hole, respectively.

In an embodiment, horizontal sections of the ring space, the opening, the through hole and the expended opening are circular, and horizontal section of the terminal component is hexagonal.

In an embodiment, the motor controller and cold plate assembly includes a plurality of terminal bases, a plurality of conductive components and a plurality of wiring terminals, wherein the plurality of terminal bases are corresponding to the plurality of the conductive components and the plurality of wiring terminals in space and number.

In an embodiment, the cold plate includes a plurality of through holes passing through the first surface and the second surface and arranged along a first direction parallel to first surface. The plurality of conductive components correspondingly pass through the plurality of through holes to connect between the plurality of terminal bases and the plurality of wiring terminals.

In an embodiment, the motor controller and cold plate assembly further includes a potting component configured to encapsulate the space formed between the plurality of terminal components and the plurality of through holes of the cold plate.

In an embodiment, the cold plate further includes a communication channel disposed on the second surface, extended along the first direction parallel to first surface, and in communication with the plurality of through holes. The potting component is integrally formed in one piece.

In an embodiment, the potting component includes a plurality of first ring ends and a plurality of connection portions formed at two opposite ends of the potting component.

In an embodiment, the potting component further includes a plurality ring grooves recessed formed adjacent to the corresponding first ring ends and spatially corresponding to the plurality of openings of the PCB.

In an embodiment, the plurality of terminal components are arranged along the first direction. Each of the plurality of wiring terminals has a high voltage wire extended along a second direction parallel to the first surface, and the second direction is perpendicular to the first direction.

In an embodiment, the plurality of wiring terminals are connected to the plurality of terminal components through screws, which are screwed in the corresponding engaged end along a third direction perpendicular to the first direction and the second direction.

In an embodiment, the motor controller and cold plate assembly further includes at least one wiring base. The at least one wiring base is fixed on the cold plate and extended along the second surface and one lateral side wall of the cold plate. The at least one wiring terminal is partially embedded in the at least one wiring base, and includes a first lead-out part and a second lead-out part. The first lead-out part and the second lead-out part are exposed from the at least the wiring base, and perpendicular to the second surface and the lateral side wall, respectively.

In an embodiment, the least one wiring base further includes a first lead trough and a second lead trough, wherein the first lead trough is arranged parallel to the second surface and extended radially outward in an X-shape with the first lead-out part as a center, and the second lead trough is parallel the lateral side wall and extended radially outward in an X-shape with the second lead-out part as a center.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a motor controller and cold plate assembly according to a first embodiment of the present disclosure and taken from the upper perspective;

FIG. 2 is a structural perspective view illustrating the motor controller and cold plate assembly according to the first embodiment of the present disclosure and taken from the lower perspective;

FIG. 3 is a schematic exploded view illustrating the motor controller and cold plate assembly according to the first embodiment of the present disclosure and taken from the upper perspective;

FIG. 4 is a schematic exploded view illustrating the motor controller and cold plate assembly according to the first embodiment of the present disclosure and taken from the lower perspective;

FIG. 5 is a cross sectional view illustrating the motor controller and cold plate assembly according to the first embodiment of the present disclosure;

FIG. 6 is a structural perspective view illustrating a motor controller and cold plate assembly according to a second embodiment of the present disclosure and taken from the lower perspective;

FIG. 7 is a schematic exploded view illustrating the motor controller and cold plate assembly according to the second embodiment of the present disclosure and taken from the upper perspective;

FIG. 8 is a schematic exploded view illustrating the motor controller and cold plate assembly according to the second embodiment of the present disclosure and taken from the lower perspective;

FIG. 9 is a cross sectional view illustrating the motor controller and cold plate assembly according to the second embodiment of the present disclosure;

FIG. 10 is a structural perspective view illustrating a motor controller and cold plate assembly according to a third embodiment of the present disclosure and taken from the upper perspective;

FIG. 11 is a structural perspective view illustrating the motor controller and cold plate assembly according to the third embodiment of the present disclosure and taken from the lower perspective;

FIG. 12 is a schematic exploded view illustrating the motor controller and cold plate assembly according to the third embodiment of the present disclosure and taken from the upper perspective;

FIG. 13 is a schematic exploded view illustrating the motor controller and cold plate assembly according to the third embodiment of the present disclosure and taken from the lower perspective;

FIG. 14 is a cross sectional view illustrating the motor controller and cold plate assembly according to the third embodiment of the present disclosure;

FIG. 15 is a structural perspective view illustrating a motor controller and cold plate assembly according to a fourth embodiment of the present disclosure and taken from the lower perspective;

FIG. 16 is a schematic exploded view illustrating the motor controller and cold plate assembly according to the fourth embodiment of the present disclosure and taken from the lower perspective;

FIG. 17 is a schematic exploded view illustrating the wiring terminal in the motor controller and cold plate assembly according to the fourth embodiment of the present disclosure;

FIG. 18 is a partial bottom view illustrating the motor controller and cold plate assembly according to the fourth embodiment of the present disclosure; and

FIG. 19 is a partial lateral side view illustrating the motor controller and cold plate assembly according to the fourth embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments.

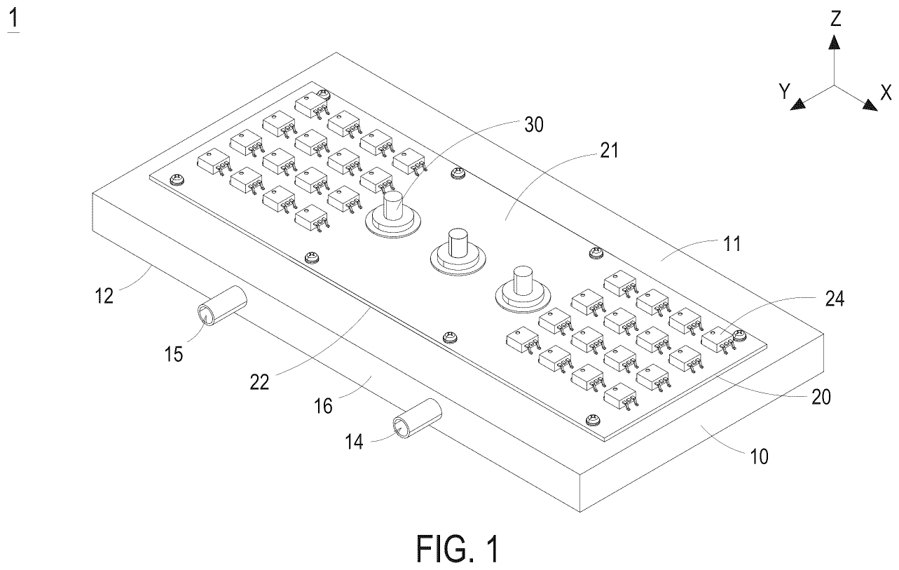

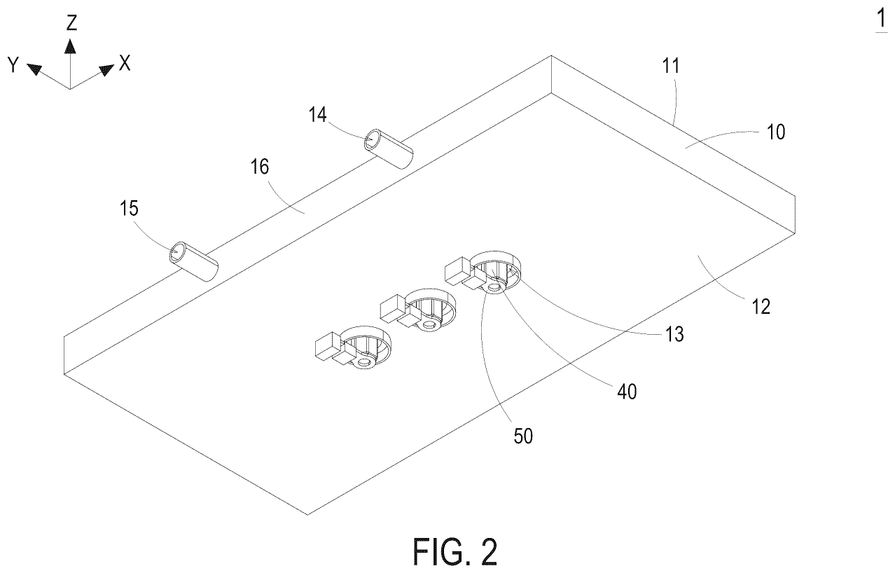

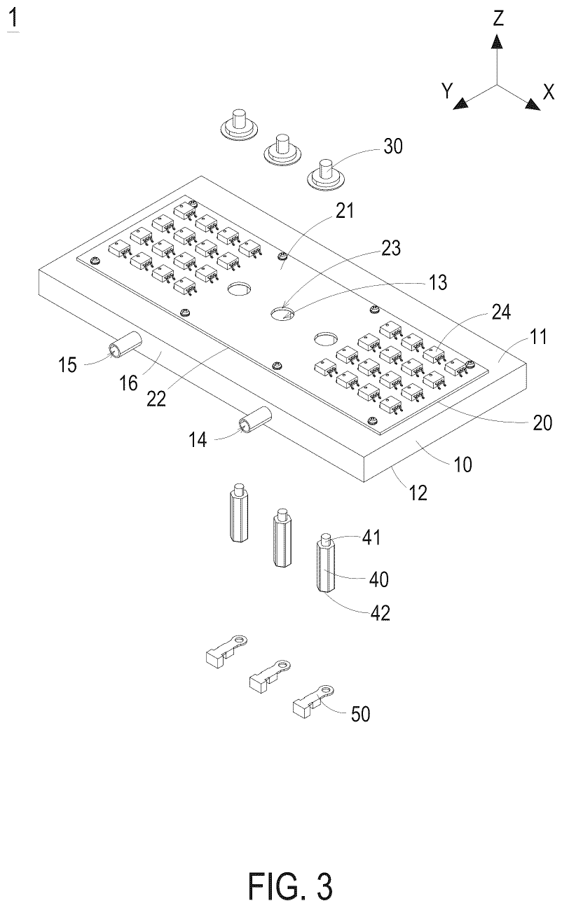

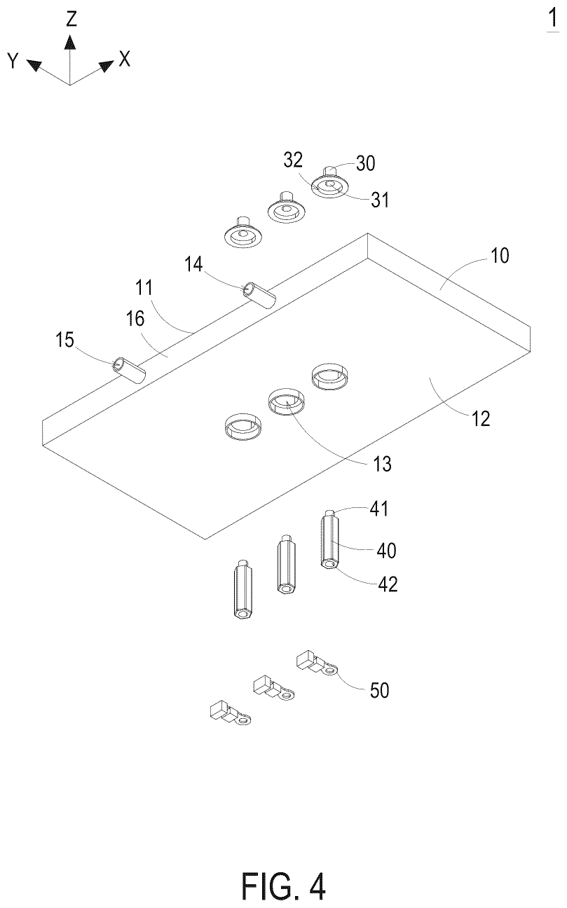

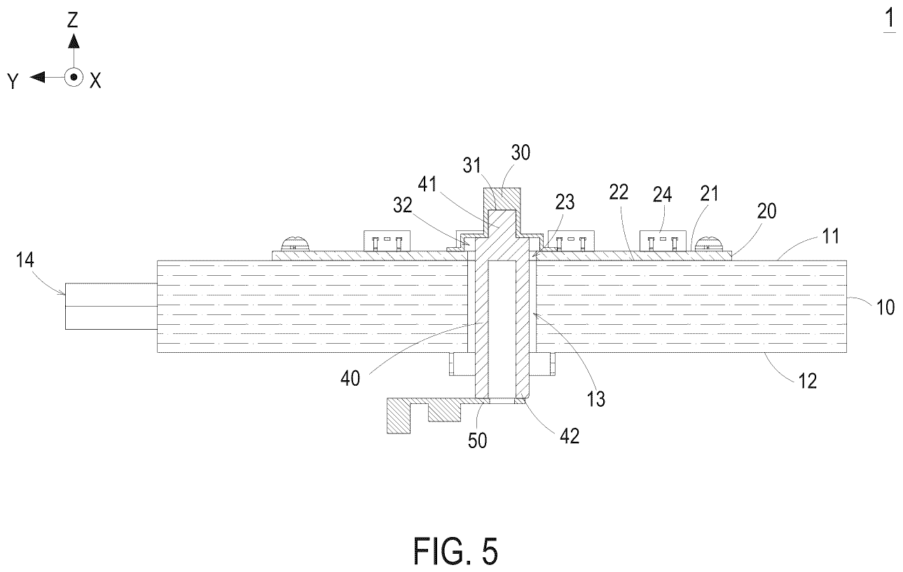

FIG. 1 is a structural perspective view illustrating a motor controller and cold plate assembly according to a first embodiment of the present disclosure and taken from the upper perspective. FIG. 2 is a structural perspective view illustrating the motor controller and cold plate assembly according to the first embodiment of the present disclosure and taken from the lower perspective. FIG. 3 is a schematic exploded view illustrating the motor controller and cold plate assembly according to the first embodiment of the present disclosure and taken from the upper perspective. FIG. 4 is a schematic exploded view illustrating the motor controller and cold plate assembly according to the first embodiment of the present disclosure and taken from the lower perspective. FIG. 5 is a cross sectional view illustrating the motor controller and cold plate assembly according to the first embodiment of the present disclosure. Referring to FIG. 1 to FIG. 5. The present disclosure provides a motor controller and cold plate assembly 1. In the embodiment, the motor controller and cold plate assembly 1 includes a cold plate 10, a PCB 20, at least one terminal base 30, at least one conductive component 40 and at least one wiring terminal 50. The at least one terminal base 30 is corresponding to the at least one conductive component 40 and the at least one wiring terminal 50 in space and number. Preferably but not exclusively, there are three terminal bases 30, three conductive components 40 and three wiring terminals 50 cooperated to form three output terminal structures. In the following descriptions, one output terminal structure is taken as an example for illustration, but the present disclosure is not limited thereto. In the embodiment, the cold plate 10 includes a first surface 11, a second surface 12, at least one through hole 13, an inlet 14 and an outlet 15. The first surface 11 and the second surface 12 are the top surface and the bottom surface opposite to each other. Preferably but not exclusively, the inlet 14 and the outlet 15 are disposed on a lateral wall 16 of the cold plate 10 and in fluid communication with an inner space (not shown) of the cold plate 10, so that the coolant liquid is transported through the inlet 14 and the outlet 15 for heat exchanging. The at least one though hole 13 passes through the first surface 11 and the second surface 12. In the embodiment, the PCB 20 can be for example but not limited to an aluminum-PCB (Al-PCB), and includes a third surface 21 and a fourth surface 22 opposite to each other. In the embodiment, the fourth surface 22 of the PCB 20 is attached to the first surface 11 of the cold plate 10 for heat dissipation, but the present disclosure is not limited thereto. In the embodiment, the PCB 20 further includes at least one opening 23 passing through the third surface 21 and the fourth surface 22. Moreover, the opening 23 is spatially corresponding to the through hole 13 of the cold plate 10. Preferably but not exclusively, in the embodiment, the PCB 20 is fixed onto the first surface 11 of the cold plate 10 through the screws, the fourth surface 22 of the PCB 20 is attached to the first surface 11 of the cold plate 10, and the opening 23 of the PCB 20 and the through hole 13 of the cold plate 10 are aligned to each other and in communication with each other. In the embodiment, the PCB 20 further includes at least one electronic component 24 configured to form a power supply unit. Preferably but not exclusively, the electronic component 24 is disposed on the third surface 21 of the PCB 20.

In the embodiment, the terminal base 30 is spatially corresponding to the opening 23 of the PCB 20 and the through hole 13 of the cold plate 10. Preferably but not exclusively, the terminal base 30 is a SMD punched terminal disposed on the third surface 21 of the PCB 20 and covers the opening 23 of the PCB 20. Preferably but not exclusive, the terminal base 30 is in shape of a cylinder hat, and includes a seal portion 31 and a ring space 32 in communication with the opening of the PCB 20 after the terminal base 30 is mounted on the third surface 21 of the PCB 20 by surface mounting technology. Preferably but not exclusively, in the embodiment, the conductive component 40 is a copper pillar or a hexagonal stud and includes a first engaged end 41 and a second engaged end 42 disposed on two opposite ends. In the embodiment, the seal portion 31 and the first engaged end 41 are a recess part and a protrusion part firmly fit with each other. In the embodiment, after the terminal base 30 is mounted on the third surface 21 of the PCB 20, the first engaged end 41 passes through the through hole 13 of the cold plate 10 and is inserted into the seal portion 31 of the terminal base 30 for electrical connection. The conductive component 40 passes through the through hole 13 but not contacts the cold plate 10, so that the conductive component is spaced apart from the cold plate 10. Preferably but not exclusively, the second engaged end 42 of the conductive component 40 includes inner threads and has the opening facing a direction perpendicular to the second surface 12 of the cold plate 10. In the embodiment, when the conductive component 40 is engaged with the terminal base 30 through the first engaged end 41, the second engaged end 42 of the conductive component 40 is exposed and protruded from the second surface 12 of the cold plate 10. Preferably but not exclusively, in the embodiment, the wiring terminal 50 is the high voltage wire connected to the second engaged end 42 of the conductive component 40, and extended along the second surface 12 of the cold plate 10. Notably, it allows to fix the wiring terminal 50 parallel to the second surface 12 onto the second engaged end 42 of the conductive component 40 through a screw (not shown). Certainly, the engaging method of the wiring terminal 50 and the second engaged end 42 of the conductive component is adjustable according to the practical requirements, and the present disclosure is not limited thereto.

Notably, in the embodiment, the terminal base 30 and the conduction component 40 are configured to form an output terminal structure passing through the cold plate 10. Compared with the conventional output terminal structure protruding from the cold plate or combined through the horizontal screw connection, the output terminal structure of the present disclosure formed by the terminal base 30 and the terminal component 40 passing through the cold plate 10 is more conducive to reducing the entire thickness of the motor controller and cold plate assembly 1 and enhancing the head dissipation efficiency thereof.

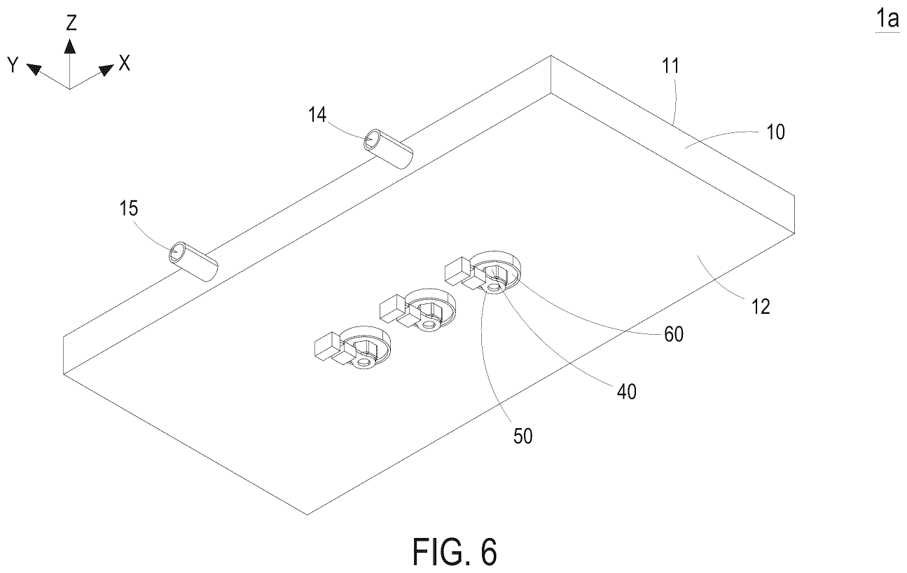

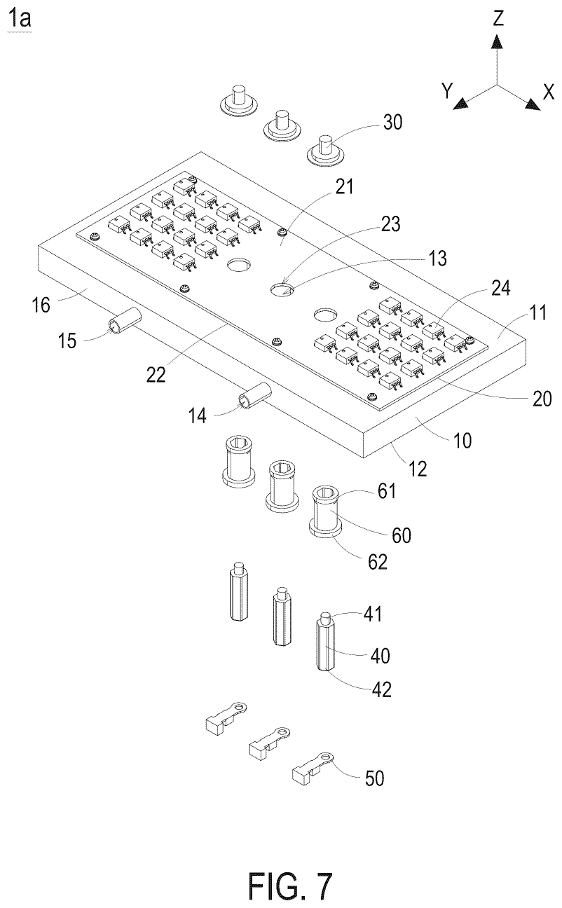

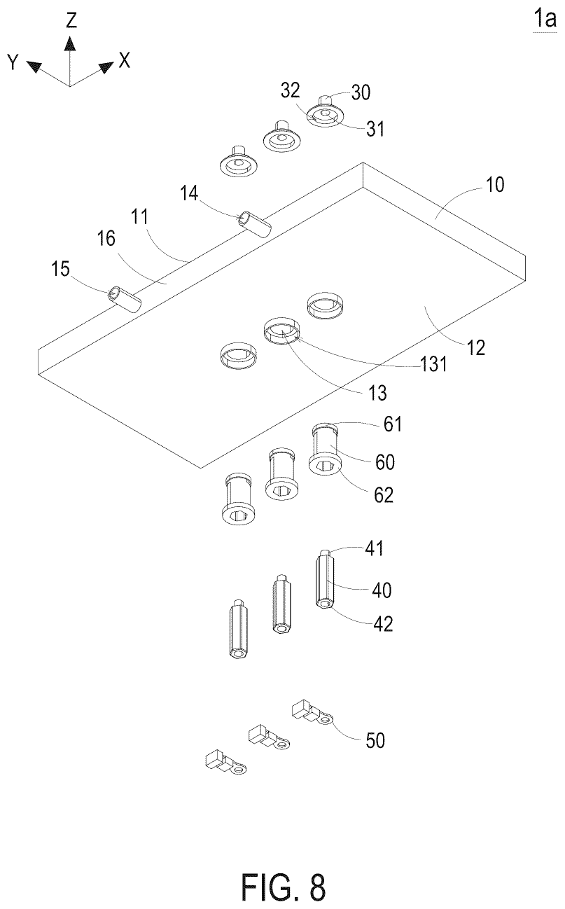

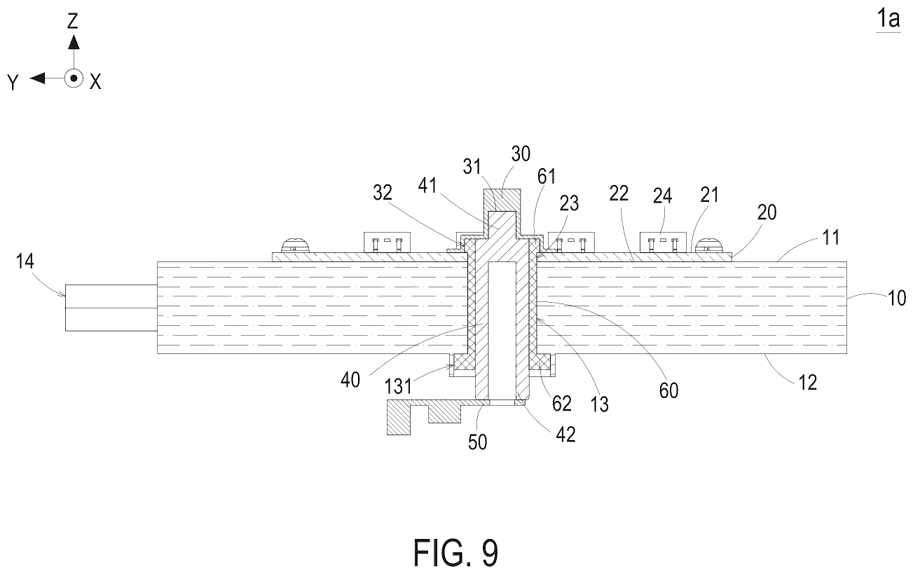

FIG. 6 is a structural perspective view illustrating a motor controller and cold plate assembly according to a second embodiment of the present disclosure and taken from the lower perspective. FIG. 7 is a schematic exploded view illustrating the motor controller and cold plate assembly according to the second embodiment of the present disclosure and taken from the upper perspective. FIG. 8 is a schematic exploded view illustrating the motor controller and cold plate assembly according to the second embodiment of the present disclosure and taken from the lower perspective. FIG. 9 is a cross sectional view illustrating the motor controller and cold plate assembly according to the second embodiment of the present disclosure. In the embodiment, the structures, elements and functions of the motor controller and cold plate assembly 1a are similar to those of the motor controller and cold plate assembly 1 in FIG. 1 to FIG. 5, and are not redundantly described herein. Please refer to FIG. 6 to FIG. 9. In the embodiment, the motor controller and cold plate assembly 1a further includes a potting component 60 configured to encapsulate the space formed between the terminal component 40 and the through hole 13 of the cold plate 10. After the terminal base 30 is mounted on the third surface 21 of the PCB 20 by surface mounting and the first engaged end 41 is firmly inserted into the seal portion 31 of the terminal base 30 for electrical connection, the ring space 32 is in communication with the exterior through the through hole 13 of the cold plate 10. The conductive component 40 is not contacted with the inner wall of the through hole 13, and a part of the ring space 32 and the through hole 13 is not occupied by the conductive component 40. In the embodiment, the potting component 60 is formed by filling the glue potting material into the part of the ring space 32 and the through hole 13 not occupied by the conductive component 40. After the glue potting material is solidified, the potting component 60 is formed between the cold plate 10 and the conductive component 40, so as to provide the adequate structural support among the cold plate 10, the terminal base 30 and the conductive component 40. Thereafter, the wiring terminal 50 can be fixed to the second engaged end 42 of the conductive component 40 firmly and stably. Since the conductive component 40 is isolated from the cold plate 10 through the potting component 60, the output terminal structure formed by the terminal base 30 and the terminal component 40 and combined with the potting component 60 is more conducive to enhancing the structural strength, providing the waterproof function and improving the head dissipation efficiency thereof. In some embodiments, the potting component 60 is formed by thermally-conductive epoxy, silicone or other encapsulation materials, and the present disclosure not limited thereto.

In the embodiment, the potting component 60 further includes a first ring end 61 and a second ring end 62 disposed on two opposite ends of the potting component 60. In the embodiment, the first ring end 61 is spatially corresponding to the ring space 32 of the conductive base 30, and received in the ring space 32. Preferably but not exclusively, the ring space 32 of the conductive base 30 has a diameter greater than that of the opening 23 of the PCB 20 and that of the through hole 13 of the cold plate 10. The diameter of the opening 23 of the PCB 20 is equal to the diameter of the through hole 13 of the cold plate 10. In the embodiment, the cold plate 10 further includes an expanded opening 131 disposed on the second surface 12 and spatially corresponding to the through hole 13. The through hole 13 is aligned with the expanded opening 131 and in fluid communication with the exterior through the expanded opening 131. Preferably but not exclusively, the expanded opening 131 has a diameter greater than that of the through hole 13, and it helps the potting material fill the space among the terminal component 40, the ring space 32 and the through hole 13 through the expanded opening 131 for forming the potting component 60. That is, the arrangement of the expended opening 131 facilitates the encapsulation operation of the potting component. Certainly, the present disclosure is not limited thereto. Furthermore, in the embodiment, the diameter of the ring space 32 and the diameter of the expended opening 131 are greater than that of the opening 23 and that of the through hole 13, respectively. After the potting component 60 is formed through the encapsulation operation, the first ring end 61 and the second ring end 62 formed on two opposite ends of the potting component 60 are firmly mounted on the third surface 21 of the PCB 20 and the second surface 12 of the cold plate 10, respectively, so that the output terminal structure formed by the terminal base 30 and the terminal component 40 are firmly combined with the potting component 60 to enhance the structural strength or provide the waterproof function. Preferably but not exclusively, the horizontal sections of the ring space 32, the opening 23, the through hole 13 and the expended opening 131 are circular, and the horizontal section of the terminal component 40 is hexagonal. Certainly, the shape of the potting component 60 is adjustable according to the practical requirements, and the present disclosure is not limited thereto.

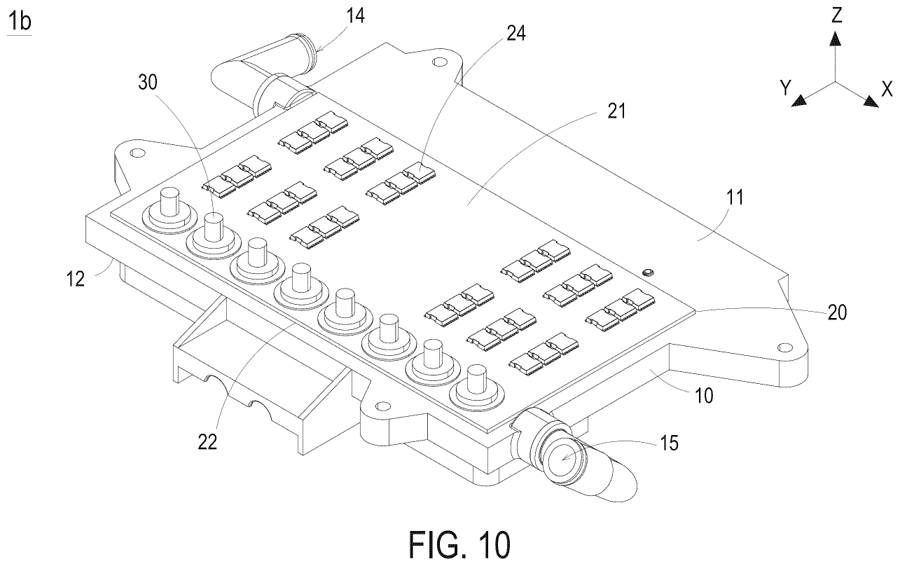

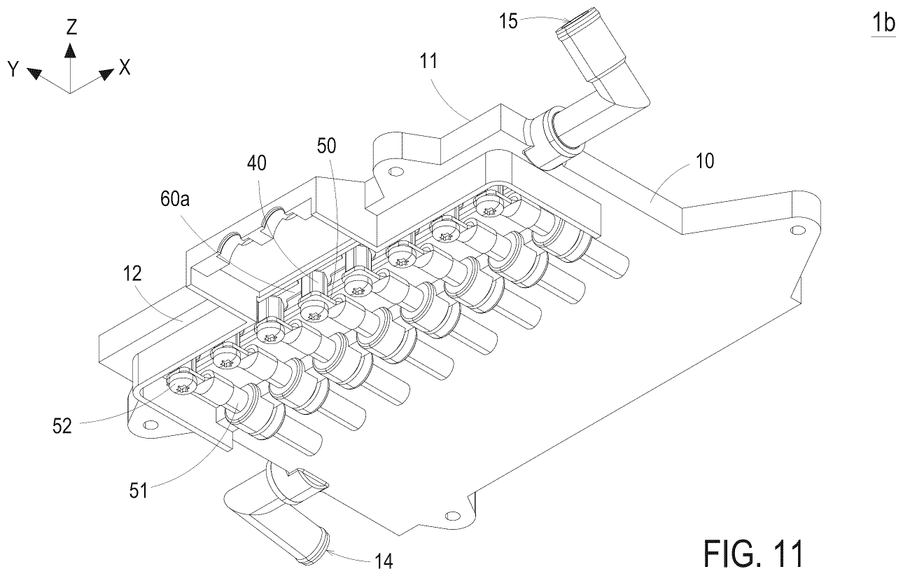

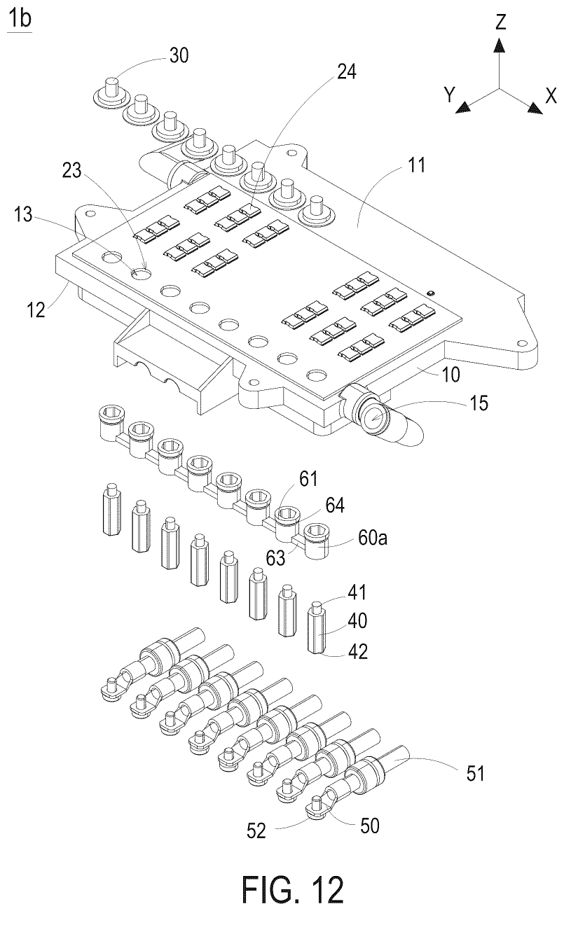

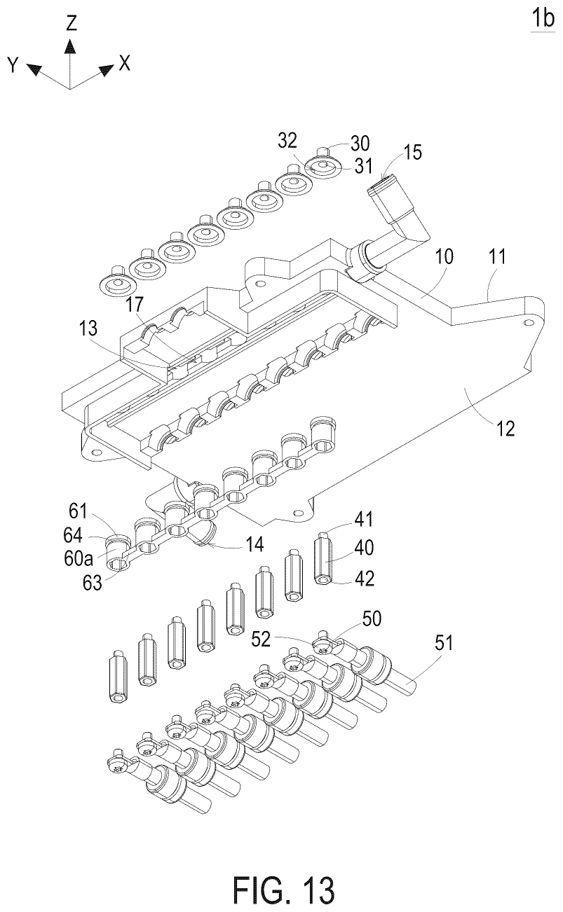

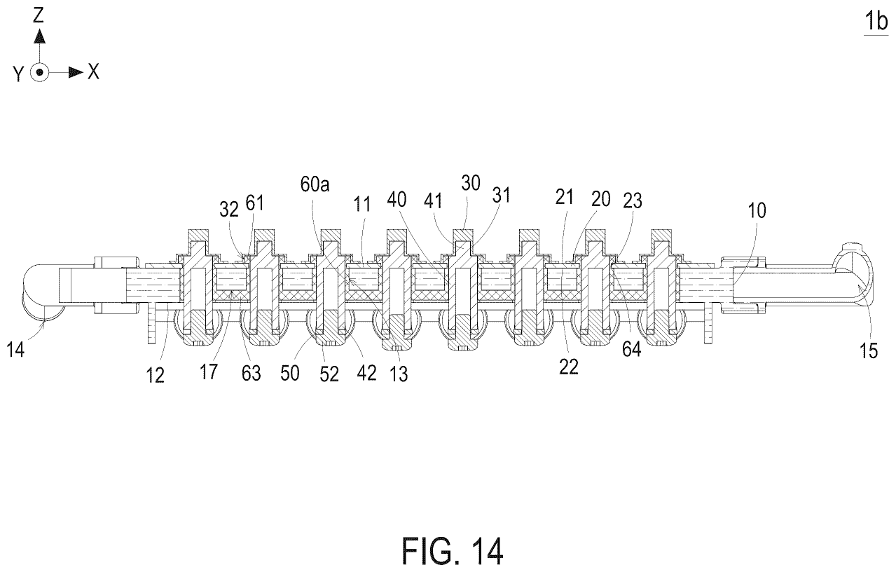

FIG. 10 is a structural perspective view illustrating a motor controller and cold plate assembly according to a third embodiment of the present disclosure and taken from the upper perspective. FIG. 11 is a structural perspective view illustrating the motor controller and cold plate assembly according to the third embodiment of the present disclosure and taken from the lower perspective. FIG. 12 is a schematic exploded view illustrating the motor controller and cold plate assembly according to the third embodiment of the present disclosure and taken from the upper perspective. FIG. 13 is a schematic exploded view illustrating the motor controller and cold plate assembly according to the third embodiment of the present disclosure and taken from the lower perspective. FIG. 14 is a cross sectional view illustrating the motor controller and cold plate assembly according to the third embodiment of the present disclosure. Please refer to FIG. 10 to FIG. 14. In the embodiment, the structures, elements and functions of the motor controller and cold plate assembly 1b are similar to those of the motor controller and cold plate assembly 1a in FIG. 6 to FIG. 9, and are not redundantly described herein. In the embodiment, the motor controller and cold plate assembly 1b includes a cold plate 10, a PCB 20, a plurality of terminal bases 30, a plurality of conductive components 40 and a plurality of wiring terminals 50. The plurality of terminal bases 30 are corresponding to the plurality of the conductive components 40 and the plurality of wiring terminals 50 in space and number. In the embodiment, the cold plate 10 includes a plurality of through holes 13 passing through the first surface 11 and the second surface 12 and arranged along the X axial direction. In the embodiment, the plurality of conductive components 40 correspondingly pass through the plurality of through holes 13 to connect between the plurality of terminal bases 30 and the plurality of wiring terminals 50. In the embodiment, the motor controller and cold plate assembly 1b further includes a potting component 60a configured to encapsulate the space formed between the terminal components 40 and the through holes 13 of the cold plate 10. In the embodiment, the cold plate 10 further includes a communication channel 16 disposed on the second surface 12, extended along the X axial direction, and in communication with the plurality of through holes 13. It helps the potting material fill the space among the terminal components 40, the ring spaces 32 and the through holes 13 through the communication channel 16 for integrally forming the potting component 60a into one piece.

Preferably but not exclusively, each ring space 32 of the conductive bases 30 has a diameter greater than that of each opening 23 of the PCB 20 and that of each through hole 13 of the cold plate 10. The diameter of each opening 23 of the PCB 20 is smaller to the diameter of each through hole 13 of the cold plate 10. After the potting component 60a is formed through the encapsulation operation, the potting component 60a is integrally formed into one piece to firmly encapsulate the plurality of conductive components passing through the plurality of through holes 13. In the embodiment, after the glue potting material for forming the potting component 60a is solidified, a plurality of first ring ends 61 and connection portions 63 are formed at two opposite ends of the potting component 60a. In the embodiment, the potting component 60a further includes a plurality ring grooves 64 recessed formed adjacent to the corresponding first ring ends and spatially corresponding to the opening 23 of the PCB 20. Since the diameter of the opening 23 of the PCB 20 is smaller to the diameter of the through hole 13 of the cold plate 10, the first end ring 61 of the potting component 60a received in the ring space 32 of the conductive base 30 can abut the third surface 21 of the PCB 20, and clamp the PCB 20 to fix on the first surface 11 of the cold plate 10. Certainly, the diameters, the shapes and the arrangements of the first end rings 61, the ring grooves 64 and the connection portions 63 are adjustable according to the practical requirements, and the present disclosure is not limited thereto. With the encapsulation of the potting component 60a formed in one piece, the output terminal structures formed by the plurality of terminal bases 30 and the plurality of terminal components 40 can be combined with the PCB 20 and the cold plate 10 firmly.

In the embodiment, the plurality of terminal components 40 are arranged along the X axial direction. Each wiring terminal 50 has the high voltage wire 51 extended along the Y axial direction. There is no enough space between the two adjacent terminal components 40 for screwing in the X axial direction. In the embodiment, each wiring terminal 50 is connected to the second engaged end 42 of the terminal component 40 through the screw, which is screwed in the corresponding engaged end 42 along the Z axial direction. The connection operations of the two adjacent terminal components 40 and the wiring terminals 50 are not interfered with each other. That is, the connection operations of the terminal components 40 and the wiring terminals 50 are simplified. Certainly, the connection method of the terminal component 40 and the wiring terminal 50 is adjustable according to the practical requirements. The present disclosure is not limited thereto and not redundantly described hereafter.

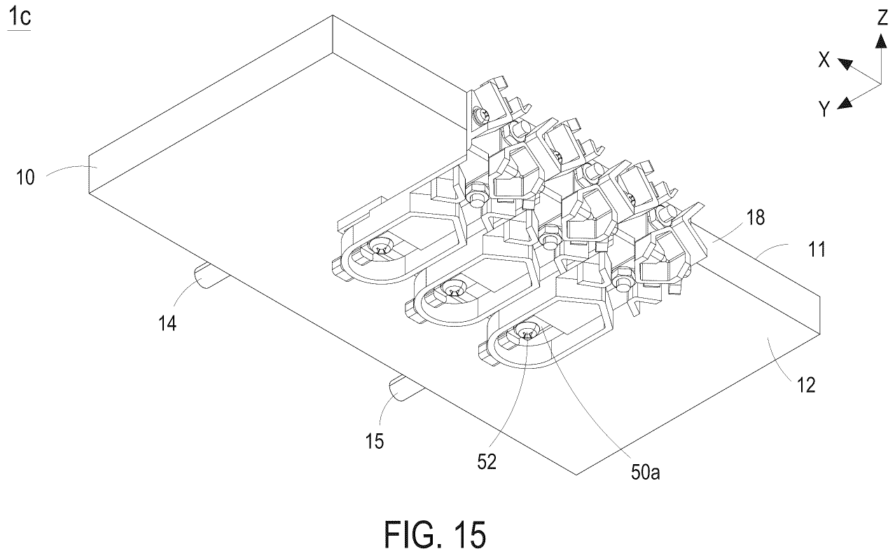

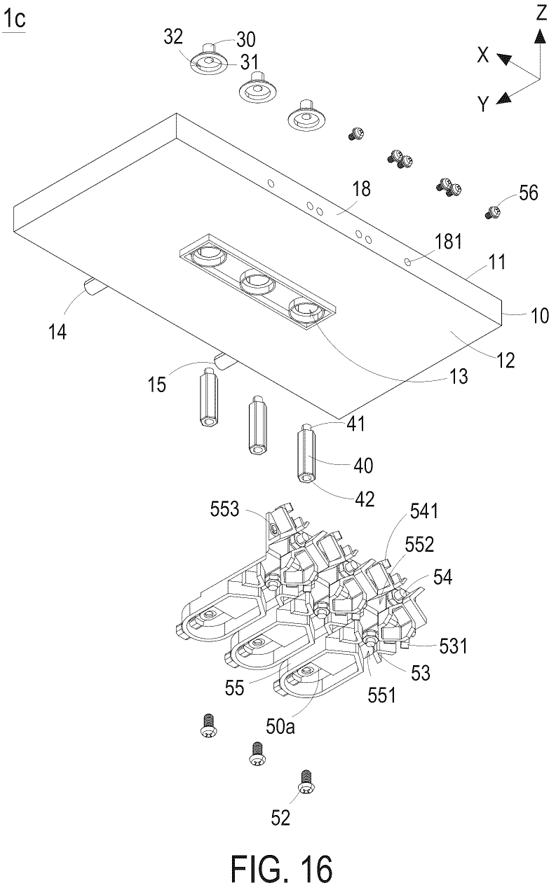

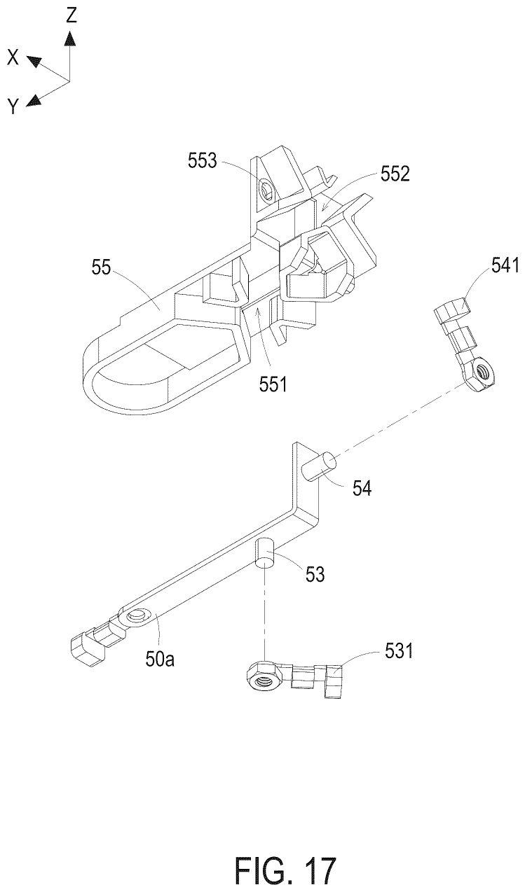

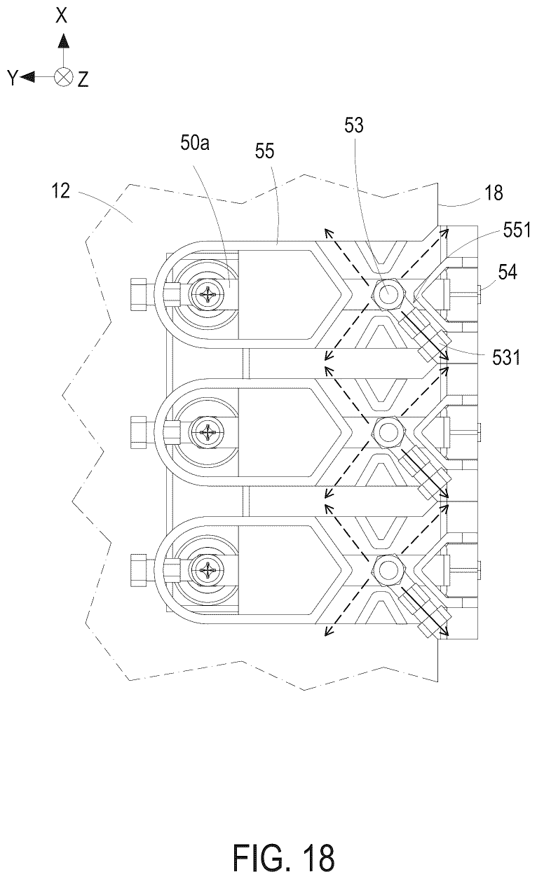

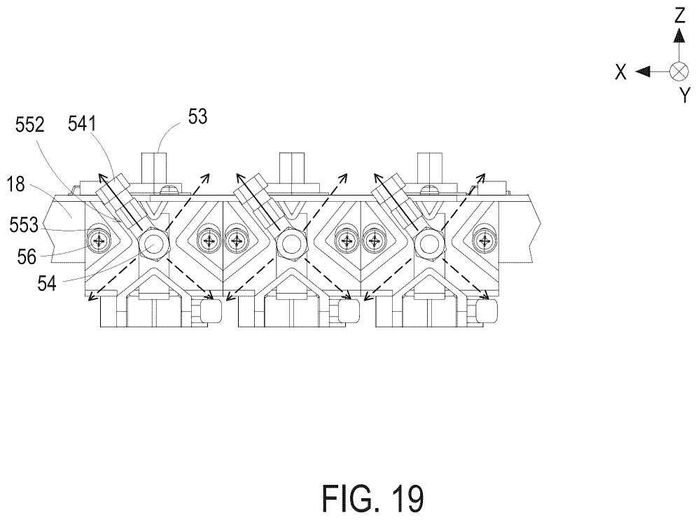

FIG. 15 is a structural perspective view illustrating a motor controller and cold plate assembly according to a fourth embodiment of the present disclosure and taken from the lower perspective. FIG. 16 is a schematic exploded view illustrating the motor controller and cold plate assembly according to the fourth embodiment of the present disclosure and taken from the lower perspective. FIG. 17 is a schematic exploded view illustrating the wiring terminal in the motor controller and cold plate assembly according to the fourth embodiment of the present disclosure. FIG. 18 is a partial bottom view illustrating the motor controller and cold plate assembly according to the fourth embodiment of the present disclosure. FIG. 19 is a partial lateral side view illustrating the motor controller and cold plate assembly according to the fourth embodiment of the present disclosure. In the embodiment, the structures, elements and functions of the motor controller and cold plate assembly 1c are similar to those of the motor controller and cold plate assembly 1 in FIG. 1 to FIG. 5, and are not redundantly described herein. Please refer to FIG. 15 to FIG. 19. In the embodiment, the motor controller and cold plate assembly 1c further includes at least one wiring base 55. The at least one wiring base 55 is fixed on the cold plate 10 and extended along the second surface 12 and one lateral side wall 18 of the cold plate 10. Preferably but not exclusively, the wiring base 55 is made of an insulating plastic material. In the embodiment, the at least one wiring terminal 50a is partially embedded in the at least one wiring base 55, and includes a first lead-out part 53 and a second lead-out part 54. The first lead-out part 53 and the second lead-out part 54 are exposed from the at least the wiring base, and perpendicular to the second surface 12 and the lateral side wall 18 of the cold plate 10, respectively. In the embodiment, the least one wiring base 55 further includes a first lead trough 551 and a second lead trough 552. Preferably but not exclusively, the first lead trough 551 is arranged parallel to the second surface 12 of the cold plate 10 and extended radially outward in an X-shape with the first lead-out part 53 as a center. In addition, the second lead trough 552 is parallel the lateral side wall 18 of the cold plate 10 and extended radially outward in an X-shape with the second lead-out part 54 as a center. In other words, each of the first lead trough 551 and the second lead trough 552 has the lead grooves in four lead-out directions for the user to choose. Thereby, the user can lead at least one wiring terminal 50a in different directions along the second surface 12 or the lateral side wall 18 of the cold plate 10 according to the practical requirements. It provides multiple combination changes and simplifies the assembly process.

In the embodiment, when the at least one wiring terminal is connected to the second engaged end 42 of the corresponding conductive component 40 through the screw 52, it is allowed to be led out through the first lead-out part 53 and/or the second lead-out part 54. When the user selects the first lead-out part 53 to lead out, the leading wire 531 can be fastened in the first lead-out part 53 through a fastener, and then the leading wire 531 is used in one of the four lead-out directions of the first lead trough 551 for accommodation. Preferably, in case of that the plurality of wiring terminals 50a need to be led out from the corresponding first lead-out part 53s, the plurality of leading wires 531 are use in the same lead-out direction of the first lead troughs 551, as shown in FIG. 18. Similarly, when the user selects the second lead-out part 54 to lead out, the leading wire 541 can be fastened in the second lead-out part 54 through a fastener, and then the leading wire 541 is used in one of the four lead-out directions of the first lead trough 551 for accommodation. Preferably, in case of that the plurality of wiring terminals 50a need to be led out from the corresponding second lead-out parts 54, the plurality of leading wires 541 are use in the same lead-out direction of the second lead troughs 552, as shown in FIG. 19. Certainly, in other embodiments, the paring applications of the first lead-out part 53, the second lead-out part 54, the first lead trough 551 and the second lead trough 552 are adjustable according to the practical requirements. The present disclosure is not limited thereto.

Preferably but not exclusively, in the embodiment, the at least one terminal base 55 further includes a first mounting hole 553, which is disposed adjacent to the second lead trough 552 and spatially corresponding to a second mounting hole 181 on the side wall 18 of the cold plate 10. The at least one terminal base 55 can be fixed on the cold plate 10 by using the screws 56 through the first mounting hole 553 and the second mounting hole 181. Certainly, in other embodiments, the manner of fixing the at least one terminal base 55 to the cold plate 10 is adjustable according to the practical requirements. The present disclosure is not limited thereto and not redundantly describe hereafter.

In summary, the present disclosure provides a motor controller and cold plate assembly having output copper pillars passing through the cold plate, to achieve the purposes of cooling and saving space at the same time. It allows to combine the glue potting surrounding the output copper pillars with the frame of the cold plate to strengthen the terminal structure. Compared with the conventional output terminal structure protruding from the cold plate or combined through the horizontal screw connection, the output terminal structure of the present disclosure passing through the cold plate is more conducive to reducing the entire thickness of the motor controller and cold plate assembly and enhancing the head dissipation efficiency thereof. Furthermore, the potting component is further formed to enhance the supporting strength between the conductive component and the cold plate and improve the head dissipation efficiency of the output terminal structure. Preferably, the potting component includes a first ring end and a second ring end disposed on two opposite ends to clamp the PCB and the cold plate. It not only reduces the entire thickness of the assembly structure, but also enhance the structural strength of the output terminal structure or provide the waterproof function. In case of that a plurality of output terminal structures are arranged closely, the potting component can be formed into one piece and has first ring ends, ring grooves and connection portions to enhance the structural strength for the output terminal structures. On the other hand, each wiring terminal is connected to the terminal component through the screw, which is screwed along the vertical direction relative the surface of the cold plate. The connection operations of the two adjacent terminal components and the wiring terminals are not interfered with each other. That is, the connection operations of the terminal components and the wiring terminals are simplified. In addition, since the lead-out directions of the wiring terminals are adjustable according to the wiring bases fixed on the cold plate, it provides multiple combination changes and simplifies the assembly process. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A motor controller and cold plate assembly, comprising:
a cold plate, comprising a first surface, a second surface and at least one through hole, wherein the first surface and the second surface are opposite to each other, and the at least one though hole passes through the first surface and the second surface;
a PCB, comprising a third surface and a fourth surface opposite to each other, and at least one opening, wherein the fourth surface of the PCB is attached to the first surface of the cold plate for heat dissipation, the at least one opening passes through the third surface and the fourth surface, and the at least one opening and the at least one through hole of the cold plate are spatially aligned to each other and in communication with each other;
at least one terminal base, spatially corresponding to the at least one opening of the PCB and the at least one through hole of the cold plate;
at least one conductive component, passing through the at least one through hole and spaced apart from the cold plate, wherein the at least one conductive component is engaged with the at least one terminal base; and
at least one wiring terminal, connected to the at least one conductive component and extended along the second surface of the cold plate.

2. The motor controller and cold plate assembly according to claim 1, wherein the at least one terminal base is a SMD punched terminal disposed on the third surface of the PCB and covers the at least one opening of the PCB.

3. The motor controller and cold plate assembly according to claim 1, wherein the terminal base is in shape of a cylinder hat, and comprises a seal portion and a ring space, which are in communication with the at least one opening of the PCB after the at least one terminal base is mounted on the third surface of the PCB by a surface mounting technology.

4. The motor controller and cold plate assembly according to claim 1, wherein the at least one conductive component is a copper pillar or a hexagonal stud and comprises a first engaged end and a second engaged end disposed on two opposite ends, and the seal portion and the first engaged end are a recess part and a protrusion part firmly fit with each other, wherein the first engaged end passes through the at least one through hole of the cold plate and is inserted into the seal portion of the at least one terminal base for electrical connection, wherein the second engaged end of the at least one conductive component comprises inner threads and has an opening facing a direction perpendicular to the second surface of the cold plate.

5. The motor controller and cold plate assembly according to claim 4, wherein the at least one conductive component is engaged with the seal portion of the terminal base through the first engaged end, and the second engaged end of the conductive component is exposed and protruded from the second surface of the cold plate, wherein the at least one wiring terminal is extended parallel to the second surface and fixed into the second engaged end of the at least one conductive component through a screw.

6. The motor controller and cold plate assembly according to claim 1, wherein the PCB further comprises at least one electronic component configured to form a power supply unit, and the at least one electronic component is disposed on the third surface of the PCB.

7. The motor controller and cold plate assembly according to claim 1, further comprising a potting component, wherein the potting component is configured to encapsulate a space formed between the at least one terminal component and the at least one through hole of the cold plate, wherein the potting component includes a first ring end and a second ring end disposed on two opposite ends.

8. The motor controller and cold plate assembly according to claim 7, wherein the first ring end is spatially corresponding to a ring space of the at least one conductive base, and received in the ring space, wherein the ring space of the at least one conductive base has a diameter greater than that of the at least one opening of the PCB and that of the at least one through hole of the cold plate, and the diameter of the at least one opening and the diameter of the at least one through hole are equal to each other.

9. The motor controller and cold plate assembly according to claim 1, wherein the cold plate further comprises an inlet and an outlet, the inlet and the outlet are disposed on a lateral wall of the cold plate and in fluid communication with an inner space of the cold plate, so as to transport a coolant through the inlet and the outlet for heat exchanging.

10. The motor controller and cold plate assembly according to claim 1, wherein the cold plate further comprises an expanded opening disposed on the second surface and spatially corresponding to the at least one through hole, and the at least one through hole is aligned with the expanded opening and in fluid communication with an exterior through the expanded opening.

11. The motor controller and cold plate assembly according to claim 10, wherein the expanded opening has a diameter greater than that of the at least one through hole, a diameter of a ring space of the at least one terminal base and a diameter of the expended opening are greater than that of the opening and that of the at least one through hole, respectively.

12. The motor controller and cold plate assembly according to claim 11, wherein horizontal sections of the ring space, the opening, the through hole and the expended opening are circular, and horizontal section of the terminal component is hexagonal.

13. The motor controller and cold plate assembly according to claim 1, comprising a plurality of terminal bases, a plurality of conductive components and a plurality of wiring terminals, wherein the plurality of terminal bases are corresponding to the plurality of the conductive components and the plurality of wiring terminals in space and number.

14. The motor controller and cold plate assembly according to claim 13, wherein the cold plate comprises a plurality of through holes passing through the first surface and the second surface and arranged along a first direction parallel to first surface, wherein the plurality of conductive components correspondingly pass through the plurality of through holes to connect between the plurality of terminal bases and the plurality of wiring terminals.

15. The motor controller and cold plate assembly according to claim 14, further comprising a potting component, wherein the potting component is configured to encapsulate the space formed between the plurality of terminal components and the plurality of through holes of the cold plate.

16. The motor controller and cold plate assembly according to claim 15, wherein the cold plate further comprises a communication channel disposed on the second surface, extended along the first direction parallel to first surface, and in communication with the plurality of through holes, wherein the potting component is integrally formed in one piece.

17. The motor controller and cold plate assembly according to claim 16, wherein the potting component comprises a plurality of first ring ends and a plurality of connection portions formed at two opposite ends of the potting component, wherein the potting component further comprises a plurality ring grooves recessed formed adjacent to the corresponding first ring ends and spatially corresponding to the plurality of openings of the PCB.

18. The motor controller and cold plate assembly according to claim 14, wherein the plurality of terminal components are arranged along the first direction, each of the plurality of wiring terminals has a high voltage wire extended along a second direction parallel to the first surface, and the second direction is perpendicular to the first direction, wherein the plurality of wiring terminals are connected to the plurality of terminal components through screws, which are screwed in the corresponding engaged end along a third direction perpendicular to the first direction and the second direction.

19. The motor controller and cold plate assembly according to claim 1, further comprising at least one wiring base, wherein the at least one wiring base is fixed on the cold plate and extended along the second surface and one lateral side wall of the cold plate, wherein the at least one wiring terminal is partially embedded in the at least one wiring base, and comprises a first lead-out part and a second lead-out part, wherein the first lead-out part and the second lead-out part are exposed from the at least the wiring base, and perpendicular to the second surface and the lateral side wall, respectively.

20. The motor controller and cold plate assembly according to claim 19, wherein the least one wiring base further comprises a first lead trough and a second lead trough, wherein the first lead trough is arranged parallel to the second surface and extended radially outward in an X-shape with the first lead-out part as a center, and the second lead trough is parallel the lateral side wall and extended radially outward in an X-shape with the second lead-out part as a center.
